(19) United States
(12) Patent Application Publication
(10) Pub. No.: US 2009/0130572 A1
(43) Pub. Date: May 21, 2009

(54) RETICLE FOR FORMING MICROSCOPIC PATTERN

(76) Inventor: Jong-Doo Kim, Eumseong-gun (KR)

Correspondence Address: SHERR & VAUGHN, PLLC, 620 HERNDON PARKWAY, SUITE 200, HERNDON, VA, 20170, US

(21) Appl. No.: 12/263,484

(22) Filed: Nov. 2, 2008

(30) Foreign Application Priority Data
Nov. 16, 2007 (KR) 10-2007-0117224

(51) Int. Cl. G03F 1/14

(52) U.S. Cl. 430/5

(57) ABSTRACT

A reticle for forming a microscopic pattern is formed that prevents a ghost image generated in a photolithography process for patterning microscopic-sized holes. The reticle may include a quartz substrate; a first pattern formed by exposing a portion of the surface of the quartz substrate; a second pattern surrounding the first pattern and including a phase shift layer; and a third pattern including an opaque layer around the second pattern.

The present application claims priority under 35 U.S.C. 119 to Korean Patent Application No. 2007-0117224 (filed on Nov. 16, 2007), which is hereby incorporated by reference in its entirety.

### BACKGROUND

In general, among processes for manufacturing a semiconductor device, a photolithography process employs various exposure apparatus which transfer a designated pattern formed on a reticle to the surface of a semiconductor substrate. To achieve high integration of semiconductor devices, a reduction projection optical system to have comparatively high throughput and excellent overlay accuracy is typically used. For example, a stepper of a step and repeat type or a scanner of a step and scan type may be used to form a microscopic pattern on a plurality of shot regions on a substrate provided with a photosensitive film applied thereto. The resolving power of such a reduction projection optical system is expressed by a formula of R=k₁×λ/NA, which is known as the Rayleigh formula. Further, the depth of focus (hereinafter, referred to as the ‘DOF’) of the projection optical system is expressed by a formula of DOF=k₂·λ/(NA)². In the equations, R represents the resolving power of the projection optical system, λ represents the wavelength of a light source, NA represents the numerical aperture of the projection optical system, and k₁ or k₂ represents a constant determined by the resolving power of a photosensitive film or other process conditions.

Thus, when forming a microscopic pattern, the Rayleigh formula indicates that a shorter wavelength light source may be used to reduce the angle of diffraction of light by a mask. Further, the aperture of the lens, i.e., the NA of the lens, may be increased to cause a large amount of the light source beam to be projected therefrom. While increasing the NA of the lens may appear to be beneficial, the increase of the size of the lens may cause various problems, such as aberration of the lens, and thus is limited. Although a lens having a large size can be used, the DOF margin of a pattern might actually be reduced and, thus, selecting a proper size lens is required. Therefore, process techniques have been developed to form a microscopic pattern using a short wavelength.

Thus, there have been other approaches for forming a small pattern compared with the limit of a conventional exposure apparatus using the conventional exposure apparatus. One out of these approaches relates to enhancing a resolving power of the system through exposure using a phase shift mask.

FIGS. 1A to 1H are longitudinal-sectional views illustrating a related process for manufacturing a phase shift mask to form a microscopic pattern.

With reference to FIGS. 1A and 1B, a resist 4 for an electron beam is applied to a reticle, on which a quartz substrate 1, a phase shift layer 2, and a chrome layer 3 are sequentially stacked. Afterwards, an E-beam writer irradiates an electron beam to the reticle provided with the resist 4, and the resist 4 is developed. Thereby, a first resist pattern 4a is formed. With reference to FIGS. 1C and 1D, the chrome layer 3 and the phase shift layer 2 are selectively removed by performing a dry etching process using the first resist pattern 4a. Thereby, an etched chrome layer 3a and an etched phase shift layer 2a are obtained. Thereafter, the first resist pattern 4a is removed.

With reference to FIGS. 1E and 1F, after a resist 5 for an electron beam is applied again to the reticle, the E-beam writer irradiates an electron beam to the reticle provided with the resist 5, and the resist 5 is developed. Thereby, a second resist pattern 5a is formed. With reference to FIGS. 1G and 1H, a portion of the chrome layer 3a, which is not masked by the second resist pattern 5a, is removed by performing a wet etching process using the second resist pattern 5a. Here, the chrome layer 3a is a selectively etched pattern obtained by the above dry etching. Thereby, a modified etched chrome layer 3b is obtained by the wet etching step. Thereafter, the second resist pattern 5a is removed thereby completing the manufacture of the phase shift mask.

In such a process, it is often the case that an undesired pattern (hereinafter, referred to as a “ghost image”) may be formed between the neighboring hole patterns. Such a ghost image serves to reduce a process margin in one or both of the photolithography process or the etching process.

### SUMMARY

Accordingly, embodiments relate to a reticle for forming a microscopic pattern for patterning microscopic-sized holes which prevents a ghost image from being generated in a photolithography process.

Embodiments relate to a reticle for forming a microscopic pattern that may include at least one of the following: a quartz substrate; a first pattern formed by exposing a portion of the surface of the quartz substrate; a second pattern surrounding the first pattern that may include a phase shift layer; and a third pattern including an opaque layer around the second pattern.

In accordance with embodiments, the first pattern may have a rectangular cross-section. The second pattern may surround the edge of the first pattern and be formed by stacking the phase shift layer having semi-transmittance over the quartz substrate. Similarly, the third pattern may surround the edge of the second pattern, and be formed by stacking the opaque layer on and/or over the phase shift layer. In embodiments, the third pattern may be formed at positions around the second pattern, separated from the respective corners of the first pattern by a predetermined distance. The opaque layer may be formed in the quartz substrate by destructing quartz crystals.

### DRAWINGS

FIGS. 1A to 1H are longitudinal-sectional views illustrating a process for manufacturing of a phase shift mask to form a microscopic pattern.

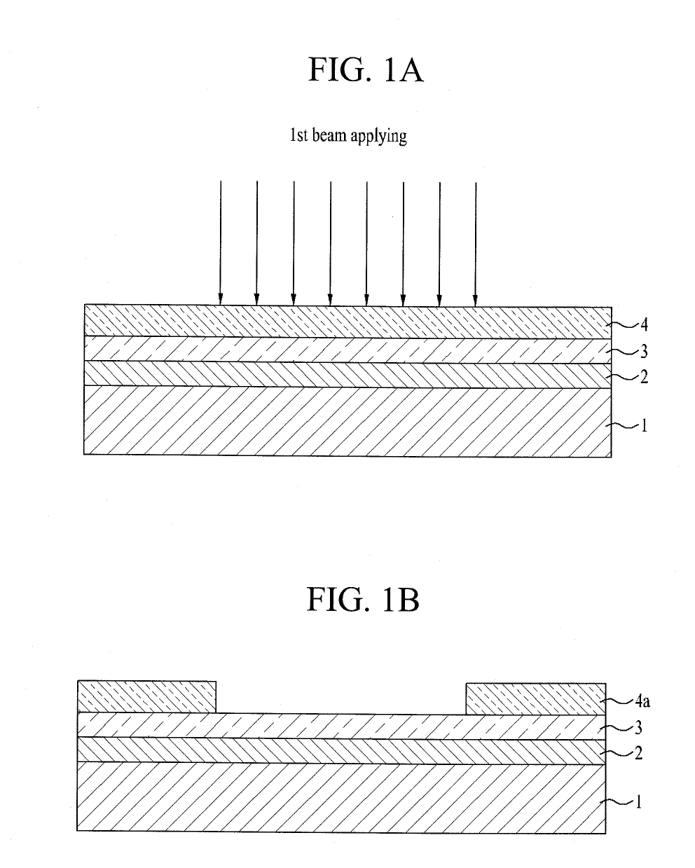

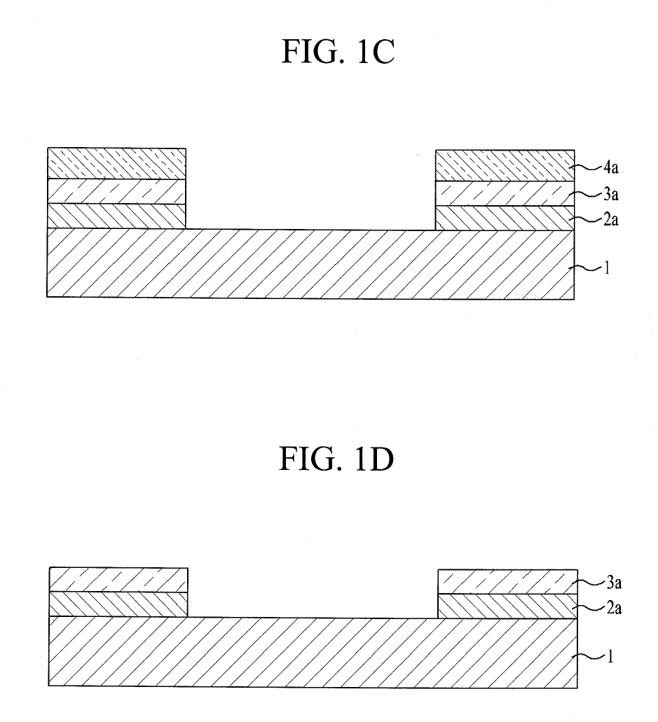

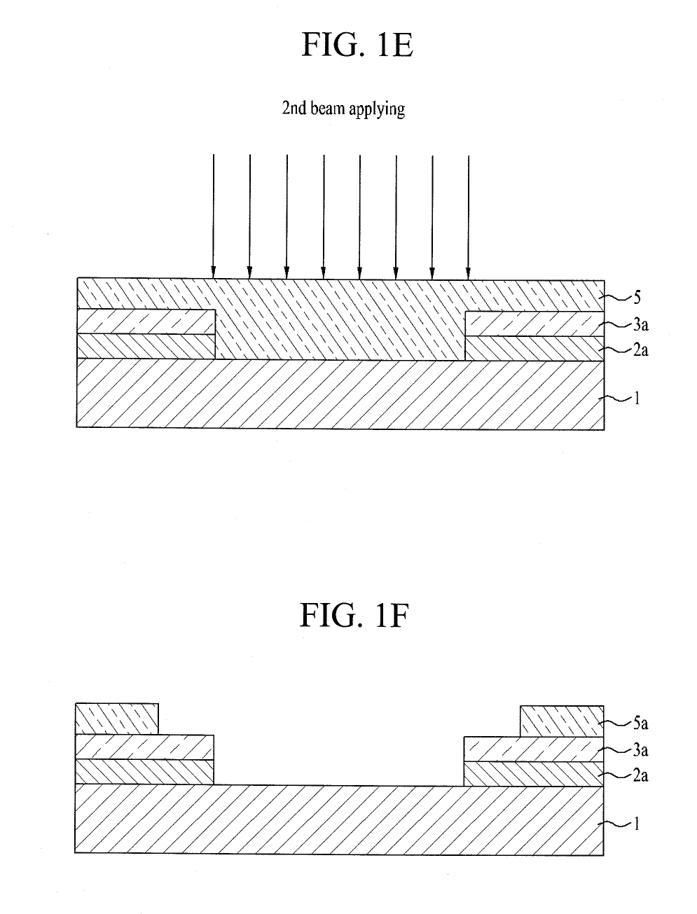

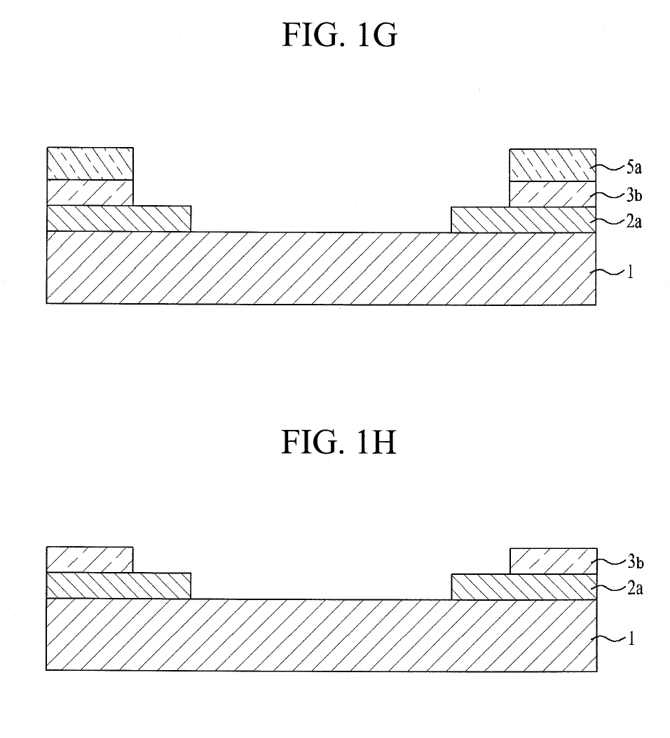

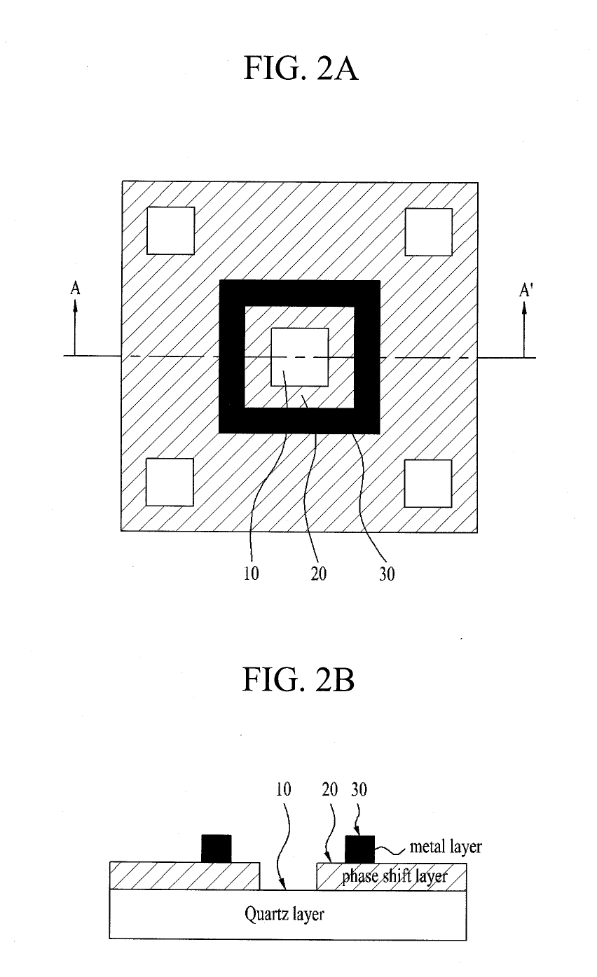

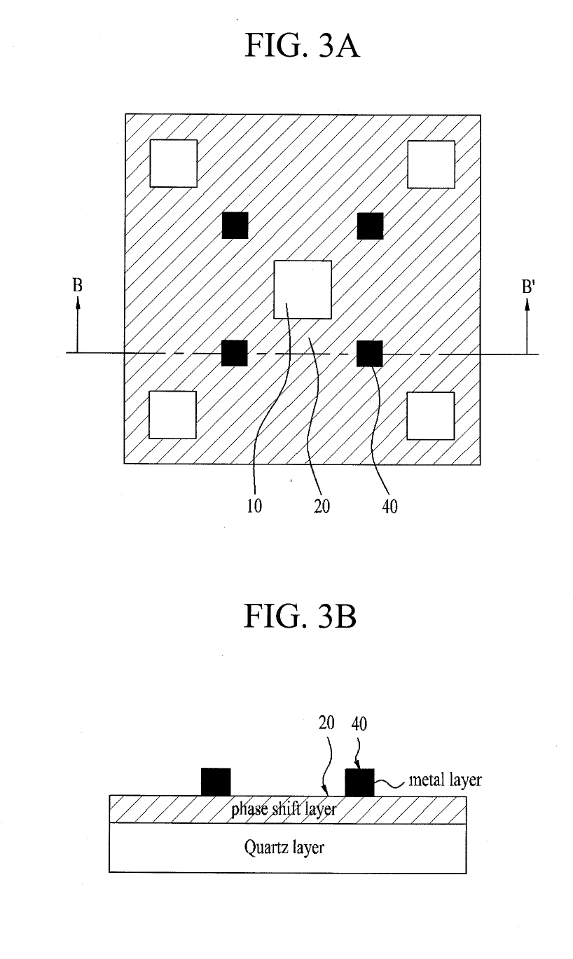

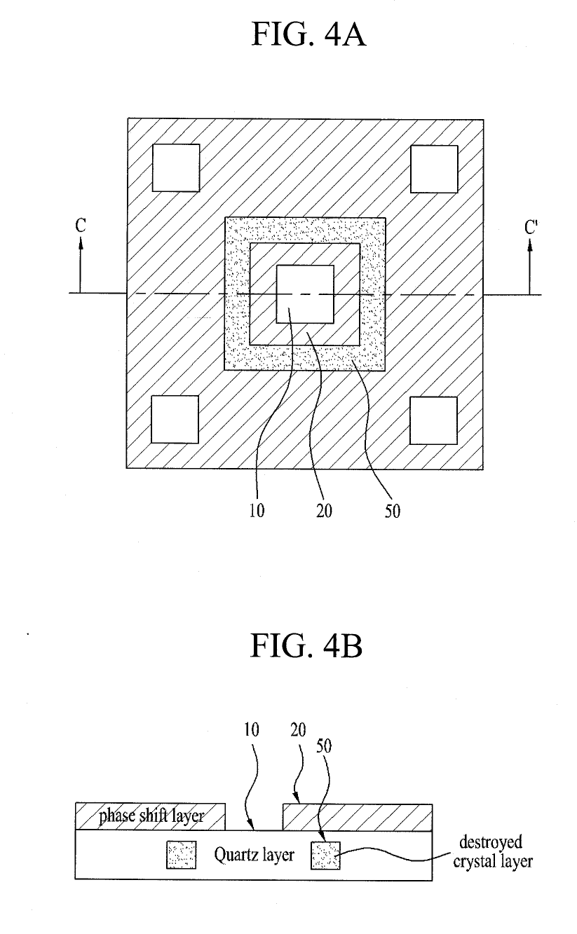

Example FIG. 2 to 4 illustrate a reticle in accordance with embodiments.

### DESCRIPTION

Hereinafter, a reticle for forming a microscopic pattern, as well as a method for making such a reticle, will be described in detail. Example FIG. 2A is a plan view illustrating the structure of a reticle in accordance with embodiments and example FIG. 2B is a longitudinal-sectional view taken along the line A-A′ of example FIG. 2A.

With reference to example FIG. 2A, the structure of the reticle in accordance with embodiments includes a first pattern 10, a second pattern 20, and a third pattern 30. As shown, the first pattern 10 may have a rectangular cross-section, which may be obtained by exposing a portion of the surface of a quartz layer. Additional pattern shapes, other than rectangular, are also contemplated for the first pattern 10 as well. In function, the first pattern 10 operates to transmit nearly all incident beams. The quartz layer may, for example, be a kind of quartz substrate.

The second pattern 20 is a pattern which may be obtained by stacking a phase shift layer on and/or over the quartz layer such that it surrounds the edge, or perimeter, of the first pattern 10. As an example, the phase shift layer may have a light transmittance of approximately 6%; although different values, both higher and lower, are also contemplated. Further, the third pattern 30 is a pattern which may be obtained by sequentially stacking the quartz layer, the phase shift layer, and a metal layer, with or without intermediate layers. As shown, the metal layer 30 surrounds the edge of the second pattern 20 that surrounds the edge of the first pattern 10. The metal layer, for example, has a light transmittance of approximately 0%.

Thus, as shown in example FIGS. 2A and 2B, the regions in which a ghost image may be generated are almost entirely shielded from light using the metal layer, thus preventing the generation of a ghost image. According to embodiments, the phase shift layer forming the second pattern 20 may be a molybdenum silicide (MoSi) layer, and the metal layer forming the third pattern 30 may be a chrome (Cr) layer or a titanium nitride (TiN) layer. Other materials having suitable functional properties may also be substituted for these example materials within the embodiments shown.

Example FIG. 3A is a plan view illustrating the structure of a reticle in accordance with embodiments, and example FIG. 3B is a longitudinal-sectional view taken along the line B-B′ of example FIG. 3A. With reference to example FIGS. 3A and 3B, the structure of the reticle in accordance with embodiments is similar to that of the reticle shown in example FIGS. 2A and 2B except that a metal layer of a third pattern 40 does not completely surround the edge of a second pattern 20 but, instead, may be formed at locations separated from the respective corners of a first pattern 10 by a designated, or predetermined, distance. Here, the locations where the metal layer of the third pattern 40 may be formed, correspond to regions in which a ghost image may be generated.

Furthermore, in example FIGS. 3A and 3B, the phase shift layer may be a molybdenum silicide (MoSi) layer, and the metal layer may be a chrome (Cr) layer or a titanium nitride (TiN) layer. Other materials having suitable functional properties may also be substituted for these example materials within the embodiments shown.

Example FIG. 4A is a plan view illustrating the structure of a reticle in accordance with embodiments, and FIG. 4B is a longitudinal-sectional view taken along the line C-C′ of example FIG. 4A.

With reference to FIGS. 4A and 4B, the structure of the reticle in accordance with embodiments includes a first pattern 10 and a second pattern 20, which are similar to those of the reticle shown in example FIGS. 2A and 2B. However, a third pattern 50 may be formed in regions in which a ghost image may be generated. This third pattern 50 may be formed by a method other than sequentially stacking a quartz layer, a phase shift layer, and a metal layer. For example, the pattern 50 may be formed by a quartz layer, a destroyed crystal layer in the quartz layer, and a phase shift layer.

A detailed description of the configurations of the first pattern 10 and the second pattern 20 shown in example FIGS. 4A and 4B, which are similar to those shown in example FIGS. 2A, 2B, 3A, and 3B, is provided above with respect to those figures and is not repeated here.

In the reticle structure shown in example FIGS. 4A and 4B, the third pattern 50 may be a pattern which surrounds the edge of the second pattern 20 and may be obtained by stacking the quartz layer including the destroyed crystal layer and the phase shift layer. The destroyed crystal layer may be formed by destroying quartz crystals in a portion of the quartz layer where ghost images may be generated. The destroyed crystal layer may be generated, for example, by using a laser. For example, the destroyed crystal layer may be an opaque layer serving to shield light in the same manner as the above-described metal layer (e.g., layers 30, 40). As described above, in embodiments, the third pattern 30, 40, or 50 includes an opaque layer having a light transmittance of approximately 0% that is formed around the second pattern 20. The second pattern 20 is partially transparent having a light transmittance above approximately 0% and below approximately 100%. According to embodiments, the third pattern having the opaque layer may be formed in regions where a ghost image may be generated, around the second pattern 20, thus preventing ghost images generated during subsequent photolithography processes.

Embodiments provide a reticle that includes a pattern for preventing a ghost image, thus preventing the ghost image generated during a photolithography process for patterning microscopic-sized holes. Thereby, it is possible to improve a process margin and a production yield in the photolithography process or the etching process.

Although embodiments have been described herein, it should be understood that numerous other modifications and embodiments can be devised by those skilled in the art that will fall within the spirit and scope of the principles of this disclosure. More particularly, various variations and modifications are possible in the component parts and/or arrangements of the subject combination arrangement within the scope of the disclosure, the drawings and the appended claims. In addition to variations and modifications in the component parts and/or arrangements, alternative uses will also be apparent to those skilled in the art.

What is claimed is:

1. A reticle comprising:
a quartz substrate having a surface;
a first pattern formed by exposing at least a portion of the surface of the quartz substrate;
a second pattern substantially surrounding the first pattern and including a phase shift layer; and
a third pattern including an opaque layer at least partially around the second pattern.

2. The reticle of claim 1, wherein the first pattern comprises a rectangular shape having a plurality of corners.

3. The reticle of claim 1, wherein the second pattern is formed by stacking the phase shift layer having semi-transmittance over the quartz substrate.

4. The reticle of claim 1, wherein the third pattern substantially surrounds an edge of the second pattern.

5. The reticle of claim 4, wherein the third pattern is formed by stacking the opaque layer over the phase shift layer.

6. The reticle of claim 4, wherein the opaque layer is a metal layer.

7. The reticle of claim 6, wherein the metal layer comprises at least one of chrome and titanium nitride.

8. The reticle of claim 2, wherein the third pattern is formed at a plurality of locations, each location separated from the respective corners of the first pattern by a predetermined distance.

9. The reticle of claim 8, wherein the third pattern is formed by stacking the opaque layer on the phase shift layer.

10. The reticle of claim 9, wherein the opaque layer is a metal layer.

11. The reticle of claim 10, wherein the metal layer comprises at least one of chrome and titanium nitride.

12. The reticle of claim 1, wherein the quartz substrate comprises the opaque layer.

13. The reticle of claim 12, wherein the opaque layer is formed in the quartz substrate by destroying a plurality of quartz crystals.

14. The reticle of claim 1, wherein the phase shift layer comprises a molybdenum silicide layer.

15. A method of forming a reticle comprising:
forming a first pattern formed by exposing at least a portion of a surface of a quartz substrate; and then
forming a second pattern substantially surrounding the first pattern, the second pattern including a phase shift layer; and then
forming a third pattern including an opaque layer at least partially around the second pattern.

16. The method of claim 15, wherein forming the second pattern includes stacking the phase shift layer over the quartz substrate.

17. The method of claim 16, wherein forming the third pattern includes stacking the opaque layer over the phase shift layer.

18. The method of claim 15, wherein forming the third pattern includes destroying a plurality of quartz crystals in the quartz substrate to form the opaque layer.

19. The method of claim 15, wherein the opaque layer comprises a metal layer.

20. The method of claim 15, wherein the phase shift layer comprises a molybdenum silicide layer.
